(19) United States
(12) Patent Application Publication
(10) Pub. No.: US 2014/0133509 A1
(43) Pub. Date: May 15, 2014

(54) LASER ASSEMBLY THAT PROVIDES AN ADJUSTED OUTPUT BEAM HAVING SYMMETRICAL BEAM PARAMETERS

(71) Applicant: DAYLIGHT SOLUTIONS, INC., (US)

(72) Inventors: Jeremy A. Rowlette, Palo Alto, CA (US); William B. Chapman, San Diego, CA (US); Michael B. Pushkarsky, San Diego, CA (US)

(73) Assignee: DAYLIGHT SOLUTIONS, INC., San Diego, CA (US)

(21) Appl. No.: 13/692,631

(22) Filed: Dec. 3, 2012

Related U.S. Application Data
(60) Provisional application No. 61/568,117, filed on Dec. 7, 2011.

(51) Int. Cl. H01S 5/34; H01S 5/0683

(52) U.S. Cl. CPC H01S 5/34; H01S 5/0683
USPC 372/50.1; 29/592.1

(57) ABSTRACT

A laser assembly (10) for providing a beam (20) includes a gain chip (12) and an axisymmetric optical assembly (16). The gain chip (12) emits an astigmatic, output beam (14). The optical assembly (16) adjusts the output beam (14) so that an adjusted output beam (20) has an adjusted first axis divergence angle and an adjusted second axis divergence angle. In certain embodiments, a magnitude of the adjusted first axis divergence angle is approximately equal to a magnitude of an adjusted second axis divergence angle in the far field.

### RELATED INVENTION

This application claims priority on U.S. Provisional Application Ser. No. 61/568,117, filed Dec. 7, 2011 and entitled “OPTICAL COLLIMATOR FOR A GAIN MEDIUM HAVING DIFFERENT BEAM PARAMETERS”. As far as permitted, the contents of U.S. Provisional Application Ser. No. 61/568,117 are incorporated herein by reference.

### BACKGROUND

A laser can be used for many things, including but not limited to testing, measuring, diagnostics, pollution monitoring, leak detection, security, pointer tracking, jamming a guidance system, analytical instruments, homeland security and industrial process control, and/or a free space communication system. In many applications, it is desirable for an output beam from the laser to propagate long distances through the atmosphere.

Recently, Quantum Cascade (“QC”) as well as Interband Cascade (IC) gain chips have been used in applications that require a mid-infrared (“MIR”) output beam. Unfortunately, the output beam from a QC gain chip can be astigmatic. Stated in another fashion, the QC gain chip has a fast axis and a slow axis, and the output beam from the QC gain chip has a fast axis beam width and a slow axis beam width that have different magnitudes. As a result thereof, standard collimating optical assembles do not, by design, achieve equal, or near-equal, far-field divergence angles for the output beam from a QC gain chip, which is highly desirable condition in applications such as, but not limited to, long-range laser targeting and in microscopy applications.

### SUMMARY

A laser assembly for providing a beam includes a gain chip and a collimating output optical assembly, which is axisymmetric about an optical axis, i.e. the central direction which light propagates away from the gain chip. The gain chip includes an output facet, and the gain chip emits an astigmatic, output beam from the output facet and propagates along the optical axis when electrical power is directed to the gain chip. The astigmatic output beam exiting the output facet has a first axis far-field divergence angle, referred to herein as the divergence angle, and a second axis far-field divergence angle, and the magnitude of the first axis divergence angle is different from the magnitude of the second axis divergence angle. The output optical assembly is positioned in the path of the output beam such that the axis of symmetry of the optical assembly is collinear with the optical axis, and the output optical assembly is positioned so that the output beam exiting the output optical assembly has an adjusted first axis divergence angle and an adjusted second axis divergence angle that are approximately equal in magnitude. With this design, a first (“fast”) axis beam waist (e.g. diameter) is approximately equal to a second (“slow”) axis beam waist (e.g. diameter) in the far field.

As provided herein, the term “radius” shall mean the “lie half-width” of the beam and the term “diameter” shall mean the “1/e width” of the beam. It should be noted that for an astigmatic beam, the fast axis radius is different from the slow axis radius. Alternatively, for a beam with a circular shaped cross-section, the fast axis radius is approximately the same as the slow axis radius.

In certain embodiments, the present invention is directed to an optical assembly that takes an astigmatic beam from a Quantum Cascade gain chip and turns it into a near circular beam in the far field through (i) the proper positioning of the lens focal plane of the optical assembly to the output facet of the Quantum Cascade gain chip, and (ii) correcting aberrations of the lens for the finite conjugate points as provided herein.

In another embodiment, the present invention is directed to an optical assembly that takes an astigmatic beam from a Quantum Cascade gain chip and turns it into a specified elliptical parameter in the far-field through (i) the proper positioning of the lens focal plane of the optical assembly to the output facet of the Quantum Cascade gain chip, and (ii) correcting aberrations of the lens for the finite conjugate points as provided herein.

As used herein, the term “far field” shall mean the region along the optical axis, z, where the condition

$$\frac{{\overline{w}}^{2}}{z λ} ≪ 1$$

is satisfied where w̅ is the effective aperture size of the optical system, and λ is the wavelength of the beam. Further, the term “near field” shall mean

$$\frac{{\overline{w}}^{2}}{z λ} > 1.$$

As a non-exclusive example, the boundary of the far-field will range between approximately 0.5 to 5 meters from the output of the optical assembly for a typical quantum cascade gain medium and optical assembly parameters.

In one embodiment, (i) the gain chip is a gain medium having a fast axis and a slow axis; (ii) the optical assembly has a front focal plane, a front principal plane, and a focal length; (iii) the front principal plane of the optical assembly is spaced apart from the output facet a separation distance along a propagation axis of the output beam; and (iv) wherein the separation distance is approximately equal to the focal length plus or minus delta (Δ). In this embodiment, delta is equal to the boundary of the Rayleigh distance of a hypothetical axisymmetric Gaussian beam having a waist of radius equal to the geometric mean of the actual waists of the fast and slow axes of the gain medium.

In one embodiment, the front principal plane of the optical assembly is spaced apart from the output facet a separation distance “L₁” along a propagation axis of the output beam; and the separation distance is calculated utilizing the following formula:

$${L}_{1} = f \pm \frac{π {w}_{x} ( 0 ) {w}_{y} ( 0 )}{λ}$$

wherein (i) wₓ(0) is the Gaussian beam radius at the output facet in the second axis; (ii) w_{y} (0) is the Gaussian beam radius at the output facet in the first axis; (iii) λ is the wavelength of the output beam; and (iv) f is a focal length of the optical assembly and is measured with respect to the front principal plane of the optical assembly.

In certain embodiments, the optical assembly has the following imaging condition for two finite conjugate pairs (S₁,S₂) located at the following prescribed positions:

$${S}_{1} = - ( \frac{λ}{π} ) \frac{{f}^{2}}{{w}_{x} ( 0 ) {w}_{y } ( 0 )}$$

$${S}_{2} = f \pm \frac{π {w}_{x} ( 0 ) {w}_{y} ( 0 )}{λ}$$

wherein (i) wₓ(0) is the Gaussian beam radius at the output facet in the slow axis; (ii) w_{y} (0) is the Gaussian beam radius at the output facet in the fast axis; (iii) λ is the wavelength of the output beam; and (iv) f is a focal length of the optical assembly and is measured with respect to a front principal plane of the optical assembly. In this embodiment, the optical aberrations of the optical assembly are corrected, i.e. are minimized, for this finite conjugate condition. This is a departure from the standard practice for aberrations to be corrected at infinite conjugates for a collimating optical assembly for a laser source.

The present invention is also directed to a method for assembling a laser assembly that generates an adjusted beam. In one embodiment, the method includes the steps of: (i) providing a gain chip that emits an astigmatic, output beam from an output facet; (ii) providing an axisymmetric collimating optical assembly; and (iii) positioning the optical assembly in the path of the output beam so that the optical assembly adjusts the output beam so that the adjusted output beam has an adjusted first axis divergence angle and an adjusted second axis divergence angle that are approximately equal in magnitude in the far field and whereby the optical assembly aberrations are corrected for the prescribed finite conjugate condition.

The present invention is also directed to a method for assembling a laser assembly that generates an astigmatic adjusted output beam having an adjusted first axis divergence angle and an adjusted second axis divergence angle, wherein a ratio of the adjusted first axis divergence angle and the adjusted second axis divergence angle in a far field is equal to a predetermined, desired ratio that is not equal to one. In this embodiment, the method includes the steps of: (i) providing a gain chip that emits an astigmatic, output beam from an output facet along a propagation axis; (ii) providing an axisymmetric collimating optical assembly having an optical axis; and (iii) positioning the optical assembly in the path of the output beam along the propagation axis with the optical axis substantially coaxial with the propagation axis, wherein the optical assembly is positioned so that the optical assembly adjusts the output beam so that the adjusted output beam has a ratio of the magnitude of the adjusted first axis divergence angle and the magnitude of the adjusted second axis divergence angle in the far field that is approximately equal to the predetermined, desired ratio.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is a simplified perspective view of a laser assembly having features of the present invention;

FIG. 1B is a simplified side view of the laser assembly of FIG. 1A in a first configuration;

FIG. 1C is a simplified side view of the laser assembly of FIG. 1A in an alternative, second configuration;

FIG. 2 is another simplified side view of the laser assembly of FIG. 1B;

FIG. 3A is a simplified graph that illustrates beam width versus distance from the gain chip for the first configuration;

FIG. 3B is another simplified graph that illustrates beam width versus distance from gain chip for the second configuration;

FIGS. 3C-3F each illustrate a simplified beam profile at alternative locations including near field and far field;

FIG. 4 is a simplified side illustration of a lens having features of the present invention and the beam;

FIG. 5 is a simplified illustration of a ray fan plot at a facet of a gain chip;

FIG. 6 is a transverse ray intercept plot at the facet location; and

FIG. 7 is a graph that illustrates RMS wavefront error vs. focus measured in waves

FIG. 8 is a simplified graph that illustrates fast axis beam diameter and slow axis beam diameter as a function of distance from the output facet;

FIG. 9A is a perspective view and FIG. 9B is a top view of a laser source having features of the present invention; and

FIG. 10 is a perspective cut-away view of a thermal pointer having features of the present invention.

### DESCRIPTION

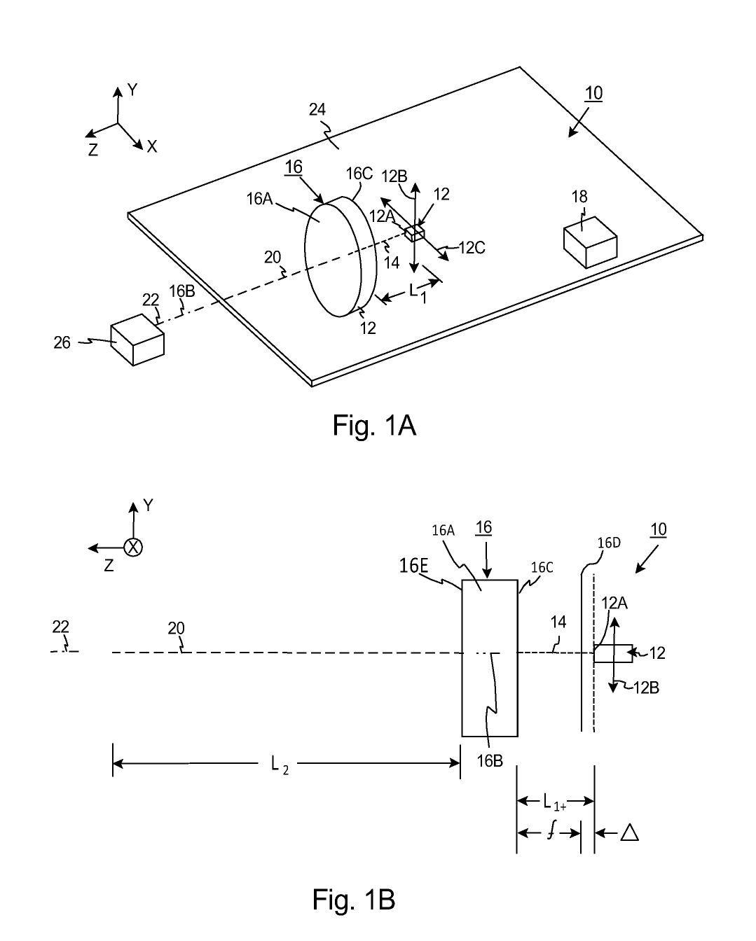

FIG. 1A is an enlarged, simplified perspective view a laser assembly 10 that includes (i) a gain chip 12 that emits an output beam 14 (illustrated with short dashes) from an output facet 12A of the gain chip 12, (ii) an output optical assembly 16, and (iii) a power source 18 that selectively directs power to the gain chip 12. The output beam 14 has a first axis divergence angle and a second axis divergence angle. In certain embodiments, the output beam 14 is astigmatic, e.g. has an elliptical shaped cross-section, and a magnitude of the first axis divergence angle is different from a magnitude of the second axis divergence angle.

As an overview, in certain embodiments, the optical assembly 16 is uniquely designed and positioned to provide an adjusted output beam 20 (illustrated with long dashes) that is substantially symmetrical in a far field, e.g. having an adjusted, first axis divergence angle and an adjusted, second axis divergence angle, and a magnitude of the adjusted, first axis divergence angle is approximately equal to a magnitude of the adjusted, second axis divergence angle.

In certain embodiments, the optical assembly 16 utilizes only axisymmetric optical components. This simplifies the design of the laser assembly 10. For example, in certain embodiments, a single axisymmetric lens 16A can be positioned at a specified location to produce the equi-divergent, adjusted output beam 20 in the far-field, and the level of spectral brightness is independent of the rotation of the lens 16A about an optical axis 16B of the optical assembly 16.

Alternatively, with the teachings provided herein, the axisymmetric optical assembly 16 can be designed and alternatively positioned to produce the desired, far-field shape of the adjusted output beam 24. With this design, the laser assembly 10 will generate the adjusted output beam 20 with a desired ratio of far-field propagation angles, including a ratio of value unity.

Some of the Figures provided herein include an orientation system that designates an X axis, a Y axis, and a Z axis. It should be understood that the orientation system is merely for reference and can be varied. For example, the X axis can be switched with the Y axis, and/or the gain chip 12 can be rotated. Moreover, these axes can alternatively be referred to as a first, second, or third axis.

The laser assemblies 10 provided herein can be used in a variety of applications, such as testing, measuring, diagnostics, pollution monitoring, leak detection, security, pointer tracking, jamming a guidance system, analytical instruments, infrared microscopes, imaging systems, homeland security and industrial process control, and/or a free space communication system.

As non-exclusive examples, the gain chip 12 can be a gain medium or an amplifier. In one embodiment, the gain chip 12 is a broadband emitter. Alternatively, the gain chip 12 can be tuned to adjust the primary wavelength of the output beam 14. For example, the gain chip 12 can include a wavelength selective element (not shown in FIG. 1) that allows the wavelength of the output beam 14 to be individually tuned. The design of the wavelength selective element can vary. Non-exclusive examples of suitable wavelength selective elements include a diffraction grating, a MEMS grating, prism pairs, a thin film filter stack with a reflector, an acoustic optic modulator, or an electro-optic modulator. Further, a wavelength selective element can be incorporated into the gain chip 12. A more complete discussion of these types of wavelength selective elements can be found in the Tunable Laser Handbook, Academic Press, Inc., Copyright 1995, chapter 8, Pages 349-435, Paul Zorabedian, the contents of which are incorporated herein by reference.

One specific example of the gain chip 12 is a Quantum Cascade (“QC”) gain medium that generates an output beam 14 that is in mid-infrared (“MIR”) range. A suitable QC gain medium 14 can be purchased from Alpes Lasers, located in Switzerland. Alternatively, for example, the gain chip 12 can be an Interband Cascade (IC) gain medium.

In certain embodiments, the gain chip 12 includes a fast axis 12B, and a slow axis 12C. In FIG. 1A, (i) the fast axis 12B of the gain chip 12 is aligned with the narrow dimension (along the Z axis) of the gain chip 12, the fast axis 12B is aligned with a growth dimension of the gain chip 12, and the fast axis 12B is parallel with the Y axis; and (ii) the slow axis 12C of the gain chip 12 is aligned with the wide dimension (along the Z axis) of the gain chip 12, the slow axis 12C is perpendicular to the growth dimension of the gain chip 12, and the slow axis 12C is parallel with the X axis. It should be noted that the fast axis 12B can also be referred to as the first axis, and the slow axis 12C can be referred to as the second axis.

As provided herein, one, non-ideal characteristic of a QC gain medium (and some other types of gain chips) is that the output beam 14 is astigmatic. This means that the output beam 14 will have an elliptical shaped cross-section, with a fast-axis beam waist and a slow-axis beam waist that do not coincide along a propagation axis 22 (the Z axis in FIG. 1) of the output beam 14. This also means that the magnitude of the fast (“first”) axis divergence angle can differ greatly from the magnitude of the slow (“second”) axis divergence angle along the propagation axis 22. As a result thereof, it is difficult to achieve equal far-field divergence angles for the output beam 14 from a QC gain medium 12.

In certain embodiments, the optical assembly 16 is a single, axisymmetric (about the optical axis), collimating lens 16 that is uniquely designed and positioned relative to the gain chip 12 to achieve approximately equal far-field divergence angles from an astigmatic output beam 12. Stated in another fashion, the invention makes use of the astigmatism to design and position a lens 16 such that the divergence of the adjusted output beam 20 is closely matched “downstream” of the lens 16A.

The size, shape, and materials utilized for the elements of the optical assembly 16 can be varied to suit the design of the gain chip 12 and the wavelength of the output beam 14. For example, suitable materials for a Mid, infrared output beam 14 include, but are not limited to materials selected from the group of Ge, ZnSe, ZnS Si, CaF, BaF or chalcogenide glass. As a more specific example, the optical assembly 16 can be a single-element, collimating axisymmetric lens 22, e.g. a coated zinc selenide (ZnSe) spherical or aspherical lens of positive optical power (typical values 400-600 m⁻¹). The lens 16A can have two refractive surfaces.

The power source 18 directs power to the gain chip 12. For example, the power source 18 can current to the gain chip 12 in a continuous or pulsed fashion.

As provided herein, a single, axisymmetric, collimating lens 16A can be positioned at a couple of alternative, unique locations relative to the gain chip 12 in order to achieve approximately equal far-field divergence angles from an astigmatic output beam 14. In each location, the optical axis 16B of the lens 16A is coaxial with the propagation axis 22.

In one embodiment, a front principal plane 16C of the optical assembly 16 is spaced apart a separation distance “L₁” from the output facet 12A of the gain chip 12 along the propagation axis 22. With this configuration, the optical assembly 16 adjusts the output beam 14 so that the adjusted output beam 20 that exits the optical assembly 16 has a far-field beam pattern whereby the adjusted first (fast) axis divergence angle and the adjusted second (slow) axis divergence angle are approximately equal in magnitude utilizing only axisymmetric optical components.

As provided herein, two unique, alternative separation distances “L₁” can be used to produce the equi-divergent adjusted output beam 20 in the far-field. More specifically, FIG. 1B is a simplified side view of the laser assembly 10 with a first embodiment of the separation distance “L₁₊”, and FIG. 1C is a simplified side view of the laser assembly 10 with a second embodiment of the separation distance “L₁₋”. In these embodiments, the laser assembly 10 includes (i) the gain chip 12, (ii) the optical assembly 16 that includes a single-element, collimating axisymmetric lens 16A, and (iii) a controlled spacing between the gain chip 12 and the lens 16. In this embodiment, the optical assembly 16 has the front principal plane (“FPP”) 16C, the front focal plane (“FFP”) 16D, and a back principal plane (“BPP”) 16E. As provided herein, in order to achieve an equi-divergent, adjusted output beam 20 in the far-field from an astigmatic output beam 14 utilizing only axisymmetric optical components, the front principal plane 16C of the optical assembly 16 is spaced apart from the output facet 24 of the gain chip 12 either of the two unique separation distances “L₁₊” or “L₁₋” provided herein.

Referring to FIGS. 1B and 1C, the separation distance “L₁” can be calculated utilizing the following formula to produce the approximately equal far-field divergent angles:

L₁=f±Δ Equation (1)

In this equation (i) f is a focal length of the optical assembly 16 and is measured with respect to the front principal plane (FPP) 16C of the optical assembly 16, and (ii) Δ is delta and is the displacement of the output facet 12A of the gain chip 12 relative to a front focal plane 16D of the optical assembly 16. In one embodiment, delta is approximately equal to the boundary of the Rayleigh distance of an axisymmetric hypothetical Gaussian beam having a waist of radius equal to the geometric mean of the actual waists of the fast axis 12B and slow axis 12C (illustrated in FIG. 1A) of the gain medium 14.

Because there is a plus-minus sign in Equation 1, there are two alternative separation distances, namely “L₁₊” (illustrated in FIG. 1B) and “L₁₋” (illustrated in FIG. 1C) that produce the approximately equal far-field divergent angles. Stated in another fashion, FIG. 1B illustrates a first solution (sometimes referred to as the (+) solution) where delta Δ is added to the focal length; and FIG. 1C illustrates a second solution (sometimes referred to as the (−) solution) where delta Δ is subtracted from the focal length. In certain designs, the solution in which delta is added to the focal length (the (+) solution illustrated in FIG. 1B) results in a smaller beam diameter in the near-field region while simultaneously yielding substantially equal far-field divergent angles for the slow axis 12C and the fast axis 12B.

As provided herein, in one embodiment, delta Δ can be calculated as follows:

$$Δ = \frac{π {w}_{x} ( 0 ) {w}_{y} ( 0 )}{λ} \qquad Equation ( 2 )$$

wherein (i) wₓ(0) is the Gaussian beam radius at the output facet 12A in the second (slow) axis 12C; (ii) w_{y} (0) is the Gaussian beam radius at the output facet 12A in the first (fast) axis 12B; and (iii) λ is the operating wavelength of the gain chip 12, e.g. the primary wavelength of the output beam.

Combining equations (1) and (2), the separation distance “L₁” can be calculated utilizing the following formula:

$${L}_{1} = f \pm \frac{π {w}_{x} ( 0 ) {w}_{y} ( 0 )}{λ} . \qquad Equation ( 3 )$$

Using the convention of Siegman (Siegman, Lasers, University Science Books, 1986) equations 1-3 can be determined utilizing the complex Gaussian beam parameter q_{x,y} (z) for the x and y axes as defined as follows:

$$\frac{1}{{q}_{x , y} ( z )} = \frac{1}{{R}_{x , y} ( z )} - j \frac{λ}{π {w}_{x , y}^{2} ( z )} \qquad Equation ( 4 )$$

where j=\sqrt{−1}. The complex beam parameter at any arbitrary distance L=L₁+L₂ where L1 is the distance from the facet to the front principle plane of the optical assembly and L2 is the observation point beyond the optical assembly both oriented along the optical axis. L is then the distance from the output facet 12A (z=0) of the gain chip 12 along the propagation axis 22 and the complex beam parameter at this observation point can then be found using the “ABCD” rule (Siegman, Lasers, University Science Books, 1986) according to Equation 5.

$${q}_{x , y} ( L ) = \frac{{F}_{11} {q}_{x , y} ( 0 ) + {F}_{12}}{{F}_{21} {q}_{x , y} ( 0 ) + {F}_{22}} \qquad Equation ( 5 )$$

Where, for reference, the relation to Seigman's notation is A=F₁₁, B=F₁₂, C=F₂₁, and D=F₂₂. Assuming that the beam waist is located at z=0 (directly at the output facet 12A of the gain chip 12) and located on the optical axis 16B, then

$${q}_{x , y} ( 0 ) = j \frac{π {w}_{x , y}^{2} ( 0 )}{λ} = j {Z}_{x , y} ( 0 ) \qquad Equation ( 6 )$$

The values for the F matrix are then found by taking the matrix product of the 3 2×2 propagation matrices F=CBA which describe the optical system shown in FIGS. 1B and 1C. The individual matrices are explicitly

$$\begin{matrix}A = [ \begin{matrix}1 & {L}_{1} \\ 0 & 1\end{matrix} ] & Equation ( 7 a ) \\ B = [ \begin{matrix}1 & 0 \\ - 1 / f & 1\end{matrix} ] & Equation ( 7 b ) \\ C = [ \begin{matrix}1 & {L}_{2} \\ 0 & 1\end{matrix} ] & Equation ( 7 c )\end{matrix}$$

were (i) n is the refractive index of the lens 16A material, (ii) R1 and R2 are the radii of curvature for the two lens interfaces, and (iii) f is the effective focal length of the optical assembly. The four individual matrix elements of F can be found using Equation 8, derived from standard matrix algebra.

$${F}_{ij} = {\sum }_{m , n} {C}_{im} {B}_{mn} {A}_{nj} \qquad Equation ( 8 )$$

Performing the above matrix multiplication, the elements of F can be calculated as follows:

F₁₁=C₁₁B₁₁A₁₁+C₁₁B₁₂A₂₁+C₁₂B₂₁A₁₁+C₁₂B₂₂A₂₁ Equation (9a)

F₁₂=C₁₁B₁₁A₁₂+C₁₁B₁₂A₂₂+C₁₂B₂₁A₁₂+C₁₂B₂₂A₂₂ Equation (9b)

F₂₁=C₂₁B₁₁A₁₁+C₂₁B₁₂A₂₁+C₂₂B₂₁A₁₁+C₂₂B₂₂A₂₁ Equation (9c)

F₂₂=C₂₁B₁₁A₁₂+C₂₁B₁₂A₂₂+C₂₂B₂₁A₁₂+C₂₂B₂₂A₂₂ Equation (9d)

Next, Equations 9a-9d, respectively, can be reduced as follows:

F₁₁=1+C₁₂B₂₁ Equation (10a)

F₁₂=A₁₂+C₁₂B₂₁A₁₂+C₁₂ Equation (10b)

F₂₁=B₂₁ Equation (10c)

F₂₂=1+B₂₁A₁₂ Equation (10d)

Next, equations 10a-10d, respectively, can be rewritten in terms of system parameters as follows:

F₁₁=1−L₂/f≈−L₂/f Equation (11a)

F₁₂=L₁+L₂−L₁L₂/f≈L₂(1−L₁/f) Equation (11b)

F₂₁=−1/f Equation (11c)

F₂₂=1−L₁/f Equation (11d)

where the limit L₂>>f, L₁ allows for further simplification. Next, the condition for the system parameters that will produce a collimated beam whose far-field divergence angles have the following fixed relationship:

θₓ=ηθ_{y} Equation (12)

where (i) θₓ is the slow axis divergence angle, (ii) θ_{y} is the fast axis divergence angle, and (iii) η is a ratio of far-field divergence angles and is some positive, non-zero scalar value.

If the limit of small divergence angles (θₓ,θ_{y}<<20 mrad), R_{x,y}(L₂)≈L₂ and w_{xy}(0)≈L₂θ_{x,y} are substituted into equation (4), it can be rewritten as follows:

$$\frac{1}{{q}_{x , y} ( z )} \approx \frac{1}{{L}_{2}} - j \frac{λ}{π {L}_{2}^{2} {θ}_{x , y}^{2}} \qquad Equation ( 13 )$$

Therefore, the far-field divergence angle can be rewritten as follows:

$$\begin{matrix} {θ}_{x , y} = \sqrt{- \frac{λ}{π {L}_{2}^{2}} \frac{1}{Im \{ \frac{1}{{q}_{x , y} ( z )} \}}} & Equation ( 14 ) \\ {θ}_{x , y} = \sqrt{- \frac{λ}{π {L}_{2}^{2}} \frac{1}{Im \{ \frac{{F}_{21} {q}_{x , y} ( 0 ) + {F}_{22}}{{F}_{11} {q}_{x , y} ( 0 ) + {F}_{12}} \}}} & Equation ( 15 ) \\ {θ}_{x , y} = \sqrt{- \frac{λ}{π {L}_{2}^{2}} \frac{1}{Im \{ ( \frac{{F}_{21} {q}_{x , y} ( 0 ) + {F}_{22}}{{F}_{11} {q}_{x , y} ( 0 ) + {F}_{12}} ) ( \frac{{F}_{11} {q}_{x , y} * ( 0 ) + {F}_{12}}{{F}_{11} {q}_{x , y} * ( 0 ) + {F}_{12}} ) \}}} & Equation ( 16 ) \\ {θ}_{x , y} = \sqrt{- \frac{λ}{π {L}_{2}^{2}} \frac{1}{Im \{ ( \frac{\begin{matrix}{F}_{11} {F}_{21} {\vert {q}_{x , y} ( 0 ) \vert}^{2} + {F}_{12} {F}_{22} + \\ {F}_{12} {F}_{21} {q}_{x , y} ( 0 ) + {F}_{11} {F}_{22} {q}_{x , y} * ( 0 )\end{matrix}}{{F}_{11}^{2} {\vert {q}_{x , y} ( 0 ) \vert}^{2} + {F}_{12}^{2}} ) \}}} & Equation ( 17 ) \\ {θ}_{x , y} = \sqrt{\frac{λ}{π {L}_{2}^{2} \vert {q}_{x , y} ( 0 ) \vert} ( \frac{{F}_{11}^{2} {\vert {q}_{x , y} ( 0 ) \vert}^{2} + {F}_{12}^{2}}{{F}_{11} {F}_{22} - {F}_{12} {F}_{21}} )} & Equation ( 18 )\end{matrix}$$

Next, the ratio of far-field divergence angles can be expressed in following Equation 19:

$$\frac{{θ}_{x}}{{θ}_{y}} ≡ η = \sqrt{\frac{\frac{λ}{π {L}_{2}^{2} \vert {q}_{x} ( 0 ) \vert} ( \frac{{F}_{11}^{2} {\vert {q}_{x} ( 0 ) \vert}^{2} + {F}_{12}^{2}}{{F}_{11} {F}_{22} - {F}_{12} {F}_{21}} )}{\frac{{λL}_{2}^{2}}{π {L}_{2}^{2} \vert {q}_{y} ( 0 ) \vert} ( \frac{{F}_{11}^{2} {\vert {q}_{y} ( 0 ) \vert}^{2} + {F}_{12}^{2}}{{F}_{11} {F}_{22} - {F}_{12} {F}_{21}} )}} \qquad Equation ( 19 )$$

Subsequently, equation 19 can be simplified as follows:

$$\begin{matrix}η = \sqrt{\frac{\vert {q}_{y} ( 0 ) \vert}{\vert {q}_{x} ( 0 ) \vert} ( \frac{{F}_{11}^{2} {\vert {q}_{x} ( 0 ) \vert}^{2} + {F}_{12}^{2}}{{F}_{11}^{2} {\vert {q}_{y} ( 0 ) \vert}^{2} + {F}_{12}^{2}} )} & Equation ( 20 ) \\ η = \sqrt{\frac{{{w}_{y} ( 0 )}^{2}}{{{w}_{x} ( 0 )}^{2}} ( \frac{{F}_{11}^{2} {\vert {q}_{x} ( 0 ) \vert}^{2} + {F}_{12}^{2}}{{F}_{11}^{2} {\vert {q}_{y} ( 0 ) \vert}^{2} + {F}_{12}^{2}} )} & Equation ( 21 ) \\ η = \frac{{w}_{y} ( 0 )}{{w}_{x} ( 0 )} \sqrt{\frac{1 + {( \frac{{F}_{12}}{{F}_{11} \vert {q}_{x} ( 0 ) \vert} )}^{2}}{{( \frac{\vert {q}_{y} ( 0 ) \vert}{\vert {q}_{x} ( 0 ) \vert} )}^{2} + {( \frac{{F}_{12}}{{F}_{11} \vert {q}_{x} ( 0 ) \vert} )}^{2}}} & Equation ( 22 ) \\ η = \frac{1}{γ} \sqrt{\frac{1 + {α}^{2}}{\frac{1}{{γ}^{4}} + {α}^{2}}} & Equation ( 23 )\end{matrix}$$

Where, when the following definitions are used to simplify the equations:

$$\begin{matrix}γ ≡ \frac{{w}_{x} ( 0 )}{{w}_{y} ( 0 )} & Equation ( 24 ) \\ α ≡ \frac{{F}_{12} λ}{{F}_{11} π {{w}_{x} ( 0 )}^{2}} = \frac{{F}_{12}}{{F}_{11} {Z}_{x} ( 0 )} & Equation ( 25 )\end{matrix}$$

For η=1, (with reference to equation 23) α must be chosen to satisfy the following relation:

$$\frac{1}{γ} \sqrt{\frac{1 + {α}^{2}}{\frac{1}{{γ}^{4}} + {α}^{2}}} = 1 \qquad Equation ( 26 )$$

Equation 26 can be rewritten as follows:

$$\frac{1 + {α}^{2}}{\frac{1}{{γ}^{4}} + {α}^{2}} = {γ}^{2} \qquad Equation ( 27 )$$

Equation 27 can be rewritten as follows:

$$1 + {α}^{2} = {γ}^{2} ( \frac{1}{{γ}^{4}} + {α}^{2} ) \qquad Equation ( 28 )$$

Equation 28 can be rewritten as follows:

$$1 + {α}^{2} = \frac{1}{{γ}^{2}} + {α}^{2} {γ}^{2} \qquad Equation ( 29 )$$

Equation 29 can be rewritten as follows:

γ²+α²γ²=1+α²γ⁴ Equation (30)

Equation 30 can be rewritten as follows:

−α²γ²(1−γ²)+(1−γ²)=0 Equation (31)

Equation 31 can be rewritten as follows:

$$α = \pm \frac{1}{γ} \sqrt{\frac{1 - {γ}^{2}}{1 - {γ}^{2}}} \qquad Equation ( 32 )$$

Equation 32 can be rewritten as follows:

$$α = \pm \frac{1}{γ} \qquad Equation ( 33 )$$

Equation 33 can be written in terms of the system parameters reduced in the far-field limit as follows:

$$\begin{matrix}α = \frac{{L}_{2} ( 1 - {L}_{1} . f )}{- {L}_{2} {Z}_{x} ( 0 ) / f} = \frac{{L}_{1} - f}{{Z}_{x} ( 0 )} = \pm \frac{1}{γ} & Equation ( 34 ) \\ Δ ≡ {L}_{1} - f = \pm {Z}_{x} ( 0 ) / γ & Equation ( 35 ) \\ Δ = \pm {Z}_{x} ( 0 ) / γ & Equation ( 36 ) \\ Δ = \pm \frac{π {w}_{x} ( 0 ) {w}_{y} ( 0 )}{λ} = \frac{π {\overline{w}}_{x , y}^{2}}{λ} & Equation ( 37 )\end{matrix}$$

It should be noted that the ratio of the far-field divergence angles (“η”) is selected to be equal to one (η=1) to achieve substantially equal far-field divergence angles. Alternatively, η can be selected to have a predetermined ratio having a value other than one to achieve a design in which the far-field divergence angles are not substantially equal. Stated in another fashion, as provided herein, the desire, far-field shape of the output beam can be selectively adjusted by selectively adjusting ratio of the far-field divergence angles η in Equation 19. This will lead to a different separation distance L₁ in Equation 1. Stated in yet another fashion, with the teachings provided herein, the axisymmetric optical assembly 16 can be designed and alternatively positioned to produce the desired, far-field shape of the adjusted output beam 20. With this design, the laser assembly 10 will generate the adjusted output beam 20 with a desired ratio of far-field propagation angles between the slow and fast axes, including a ratio of value unity.

In the embodiment where η is specifically chosen to be a value not equal to unity, the lens front principle plane of the optical assembly should be positioned at a delta given by

$$Δ = \pm \frac{π {w}_{x} ( 0 ) {w}_{y} ( 0 )}{λ} \sqrt{\frac{η - {γ}^{2}}{1 + {ηγ}^{2}}} = \frac{π {\overline{w}}_{x , y}^{2}}{λ} \sqrt{\frac{η - {γ}^{2}}{1 + {ηγ}^{2}}} . \qquad Equation ( 38 )$$

In summary, in certain embodiments, the prescription for achieving substantially equal far-field divergence angles for a gain chip 12 with an output beam 14 having different beam parameters, i.e. wₓ(0)≠w_{y}(0), for the two primary axes, is as follows: position the output facet 12A a distance (delta Δ) to the right or left of the front focal plane 16D relative to its front principal plane 16C by an amount equal to the boundary of the Rayleigh distance of a hypothetical axisymmetric Gaussian beam having a waist of radius equal to the geometric mean of the actual waists of the fast and slow axes of the gain chip 12. Though the design prescription is derived assuming a paraxial system with a single thin lens element, the final expression is directly applicable to a real system with a lens 16A of finite thickness. This is because the prescription calls for a displacement of the output facet 12A relative to the front focal plane 16D rather than an absolute quantity.

Referring back to FIG. 1A, it should be noted that because of manufacturing tolerances in the gain chip 12 and the optical assembly 16, the calculated separation distance “L₁” may only be an approximate location of the relative position of the optical assembly 16 relative to the gain chip 12. As provided herein, during assembly of the laser assembly 10, the gain chip 12 can be fixed to a mounting base 24 (via a chip mount (not shown)) and the optical assembly 16 can be positioned in front of the gain chip 12 on the propagation axis 22 spaced apart the separation distance “L₁”. Next, power from the power source 18 can be directed to the gain chip 12 and an analyzer 26 (illustrated as a box) can be used to measure (i) the fast axis beam width at multiple locations along the propagation axis 22, (ii) the slow axis beam width at multiple locations along the propagation axis 22, (iii) the fast axis divergence angle at multiple locations along the propagation axis 22, and/or (iv) the slow axis divergence angle at multiple locations along the propagation axis 22. As a non-exclusive example, the analyzer 26 can be a two dimensional infrared imager.

Subsequently, the position of the optical assembly 16 can be slightly adjusted along the propagation axis 22 (while continuously or intermittently monitoring with the analyzer 26) until (i) the far-field, fast axis beam width is approximately equal to the far-field slow axis beam width; and/or (ii) the far-field, fast axis divergence angle is approximately equal to the slow axis divergence angle. Next, the optical assembly 16 can be fixedly secured to the mounting base 24 to fix the relative position of the gain chip 12 and the optical assembly 16.

As non-exclusive examples, the relative position of the optical assembly 16 and the gain chip 12 can be adjusted until the far-field, fast axis divergence angle is within approximately 0.5, 1, 2, 4, 6, 8, 10 percent of the far-field, slow axis divergence angle. Stated in another fashion, the relative position of the optical assembly 16 and the gain chip 12 can be adjusted until the far-field, fast axis beam width is within approximately 0.5, 1, 2, 4, 6, 8, 10 percent of the far-field, slow axis beam width.

Alternatively, it should be noted that the optical assembly 16 can first be fixed to the mounting base 24, and subsequently, the gain chip 12 can be moved and secured to the mounting base 24.

Still alternatively, in the design in which an unequal far-field divergence is desired (e.g. ratio of far-field divergence is not equal to one), the separation distance “L₁” is calculated to achieve the desired, far-field shape of the adjusted output beam 24. Next, during assembly of the laser assembly 10, the gain chip 12 can be fixed to the mounting base 24, and the optical assembly 16 can be positioned in front of the gain chip 12 on the propagation axis 22 spaced apart the separation distance “L₁”. Next, power from the power source 18 can be directed to the gain chip 12 and the analyzer 26 can be used to measure (i) the fast axis beam width at multiple locations along the propagation axis 22, (ii) the slow axis beam width at multiple locations along the propagation axis 22, (iii) the fast axis divergence angle along the propagation axis 22, and/or (iv) the slow axis divergence angle along the propagation axis 22. Subsequently, the position of the optical assembly 16 can be slightly adjusted along the propagation axis 22 (while continuously or intermittently monitoring with the analyzer 26) until (i) the desired ratio of the far-field, fast axis beam width and the far-field slow axis beam width is achieved; and/or (ii) the desired ratio of the far-field, fast axis divergence angle and the slow axis divergence angle is achieved. Next, the optical assembly 16 is fixedly secured to the mounting base 24 to fix the relative position of the gain chip 12 and the optical assembly 16.

Alternatively, the optical assembly 16 can first be fixed to the mounting base 24, and subsequently, the gain chip 12 can be moved and secured to the mounting base 24.

The ratio of the far-field divergence angles (“η”) can also be chosen to have a value (predetermined ratio) other than unity. As non-exclusive examples, ratio of the far-field divergence angles (“η”) can be selected to be approximately 0.7, 0.8, 0.9, 1.1, 1.2, or 1.3 provided that the condition η>γ² is met.

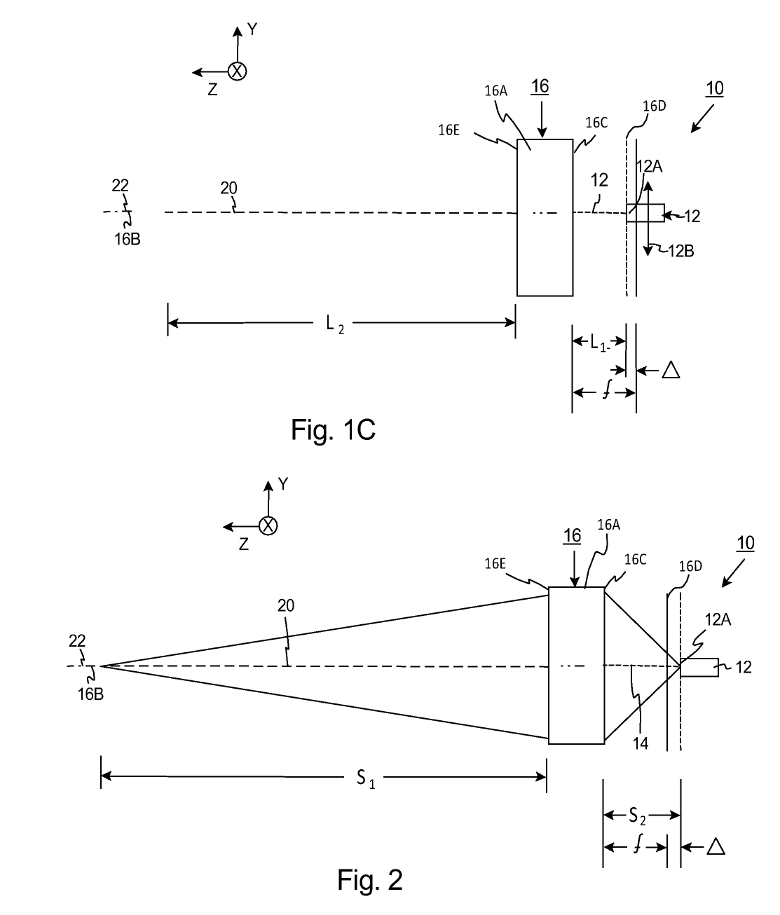

FIG. 2 is another simplified side view of the laser assembly 10 including the gain chip 12 and the optical assembly 16 of FIG. 1B. As provided herein, in certain embodiments, the present invention discloses a prescription for optimizing an axisymmetric collimation optical assembly 16 for a gain chip 12 which can be used to produce an adjusted collimated beam 20 with far-field beam divergence approximately equal in two axes orthogonal to the optical axis 16B and the propagation axis 22 which are coaxial.

Once the optimal position of the optical assembly 16 is determined as provided above, the next step is to minimize the aberrations for the optical assembly 16 for a gain chip 12 located at the object conjugate which images at the output facet 12A. The prescription is derived assuming a paraxial system with a single thin lens element 16A, but is directly applicable to a real system with a lens 16A of finite thickness since the final prescription is a value of the displacement of the output facet 12A relative to the focal plane rather than a physical surface of the optical system.

More specifically, one non-exclusive example of an axisymmetric aspheric lens 16A which collimates a Quantum Cascade (“QC”) gain chip 12 and produces equal far-field divergent angles for the two axes orthogonal to the optical axis 16B is provided herein. This design is optimized for a QC gain chip 12 having beam radius at the output facet 12A of wₓ(0)=3.7 microns (μm) (slow axis beam radius) and w_{y}(0)=2.4 microns (μm) (fast axis beam radius), and has an operating wavelength of approximately 4.6 microns (μm). The lens 16A is constrained to have a focal length of 1.812 millimeters and the aberrations are minimized for a finite image-object conjugate pair located at distances S1 and S2 as illustrated in FIG. 2. It should be noted that S2 is equal to the separation distance “L₁” illustrated in FIGS. 1A-1C and described above.

As provided herein, the collimating optical assembly 16 can be optimized, i.e. aberrations minimized, for the following imaging condition for two finite conjugate pairs (S₁,S₂) as shown in FIG. 2 located at the following prescribed positions:

$$\begin{matrix}{S}_{1} = - ( \frac{λ}{π} ) \frac{{f}^{2}}{{w}_{x} ( 0 ) {w}_{y} ( 0 )} & Equation ( 39 ) \\ {S}_{2} = f \pm \frac{π {w}_{x} ( 0 ) {w}_{y} ( 0 )}{λ} & Equation ( 40 )\end{matrix}$$

wherein (i) wₓ(0) is the Gaussian beam radius at the output facet 12A in the second (slow) axis; (ii) w_{y} (0) is the Gaussian beam radius at the output facet 12A in the first (fast) axis; (iii) λ is the operating wavelength of the gain medium (e.g. the center wavelength of the output beam 14); and (iv) f is a focal length of the optical assembly 16 and is measured with respect to the front principal plane 16C of the optical assembly 16.

As provided above, S2 is equal to L1. Thus equation (39) is equivalent to equation (3). Further, equation (38) can be determined as follows:

$$\begin{matrix}\frac{1}{{S}_{2}} - \frac{1}{{S}_{1}} = \frac{1}{f} & Equation ( 41 ) \\ {S}_{1} = - \frac{{f}^{2} + Δ f}{Δ} \approx - \frac{{f}^{2}}{Δ} & Equation ( 42 ) \\ {S}_{1} \approx - ( \frac{λ}{π} ) \frac{{f}^{2}}{{w}_{x} ( 0 ) {w}_{y} ( 0 )} & Equation ( 43 )\end{matrix}$$

In the non-exclusive embodiment described above, the output beam 14 for the QC gain chip 12 has radius values of wₓ(0)=3.7 microns (μm) and w_{y}(0)=2.4 microns (μm), and a wavelength of approximately 4.6 microns (μm), and the optical assembly 16 has a focal length of 1.81 millimeters, the source point to be used in optimizing the lens 22 should be located at a distance of five hundred and forty (540) millimeters to the left of the collimating lens 22. This is a substantial departure from the standard approach which places S1 at negative infinity.

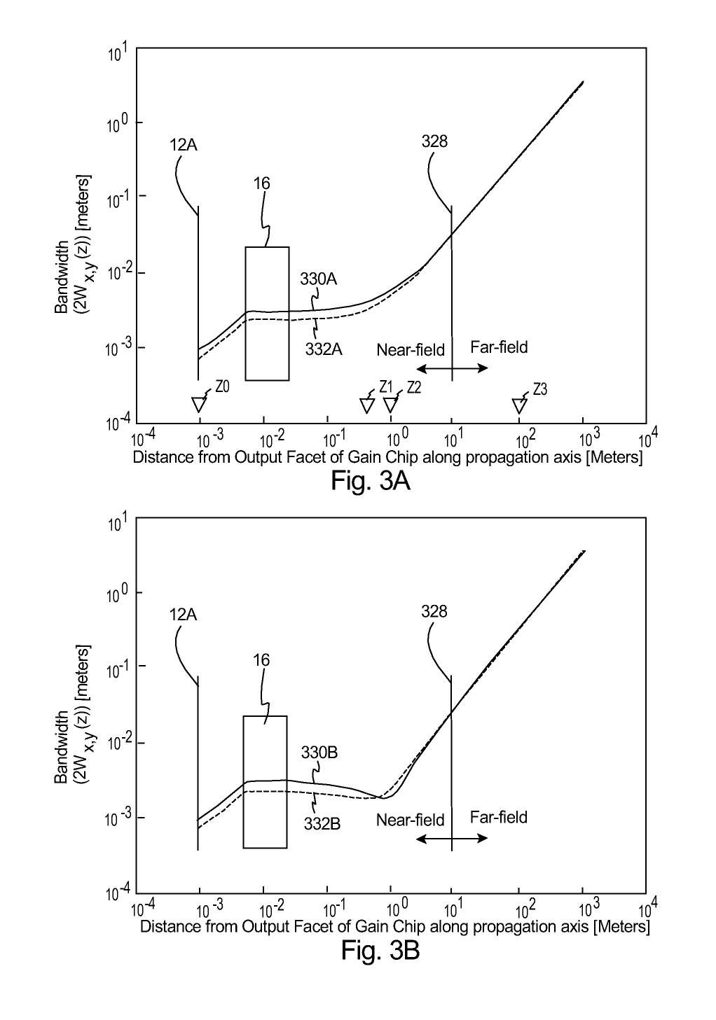

For this non-exclusive example, S1 is then set to five hundred and forty (540) millimeters to the left of the collimating lens 16A in a manner consistent with common high-numerical aperture (NA) lens design convention where light travels from left to right from low NA object space to high-NA image space. It should be noted that in certain Figures (e.g. FIGS. 1A-1C and 2), the light is illustrated as propagating from the right to the left. Alternatively, in other Figures (e.g. FIGS. 3A and 3B), the light is illustrated as propagating from the left to the right.

Table 1 below lists a lens prescription for a suitable example of an axisymmetric collimating asphere lens 16A with effective focal length (EFL) of 1.81 millimeters. All units in the tables are in millimeters unless otherwise indicated.

TABLE 1

| | Surface 1 | | | | | | Surface 2 |
|---|---|---|---|---|---|---|---|
| | R₁ | L₁₂ | k | A₆ (mm⁻⁵) | A₈ (mm⁻⁷) | A₁₀ (mm⁻⁹) | R2 |
| New | 2.593 | 3.08 | −0.671 | −3.843 × 10⁻⁴ | −1.781 × 10⁻⁴ | 2.082 × 10⁻⁵ | inf |
| Design | | | | | | | |
| Baseline | 2.593 | 3.19 | −0.637 | −3.563 × 10⁻⁴ | −1.798 × 10⁻⁴ | 1.910 × 10⁻⁵ | inf |
| Design | | | | | | | |

Table 2 below lists Final lens characteristics for this embodiment.

TABLE 2

| | | | EFL | WD | RMS |
|---|---|---|---|---|---|
| | F/# | NA | (mm) | (mm) | error |
| New Design | 0.453 | 0.74 | 1.812 | 0.547 | <λ/20 |
| Baseline | 0.453 | 0.74 | 1.812 | 0.500 | <λ/20 |
| Design | | | | | |

In these tables, (i) R1 is the radius of curvature distal side (opposite the gain chip 12) of the lens 16A, (ii) L12 is the thickness of the lens 16A along the optical axis 16B, (iii) k is the conic constant of the optical assembly 16, (iv) A6, A8, and A10 are higher order polynomial coefficients for 6^{th}, 8^{th}, and 10^{th} order respectively; (v) R2 is the radius of curvature of the proximal side (facing the gain chip 12) of the lens 16A and is planar (equal to infinity); (vi) NA is the numerical aperture of the lens 16A; (viii) EFL is effective focal length of the optical assembly 16; (iv) WD is working distance of the optical assembly 16, and (x) RMS error is the root mean square error.

FIGS. 3A and 3B are alternative, simplified graphs that illustrate the beam width versus distance along the propagation axis from the output facet 12A (of the gain chip). In this example, the optical assembly 16 is also illustrated, as well as a dividing line 328 that represents the distance away from the output facet 12A that is in the near-field (to the left of the dividing line) and that is in the far-field (to the right of the dividing line). In these examples, the optical assembly 16 has an effective focal length (f) of 2.54 millimeters.

For the graph illustrated in FIG. 3A, the optical assembly 16 is separated from output facet 12A, the separation distance “L₁₊,” as described above and illustrated in FIG. 1B. Stated in another fashion, FIG. 3A illustrates the beam width (2w_{x,y}(z)) as a function of propagation distance from the output facet 12A for the plus solution. More specifically, in FIG. 3A, (i) the solid, curved line 330A represents the fast axis beam width versus propagation distance from the output facet 12A for the plus solution, and (ii) the dashed, curved line 332A represents the slow axis beam width versus propagation distance from the output facet 12A for the plus solution.

In contrast, for FIG. 3B, the optical assembly 16 is separated from output facet 12A, the separation distance “L₁₋” as described above and illustrated in FIG. 1C. Stated in another fashion, FIG. 3B illustrates the beam width (2w_{x,y}(z)) as a function of propagation distance from the output facet 12A for the minus solution. In FIG. 3B, (i) the solid, curved line 330B represents the fast axis beam width versus propagation distance from the output facet 12A for the minus solution, and (ii) the dashed, curved line 332B represents the slow axis beam width versus propagation distance from the output facet 12A for the minus solution.

In these examples, for the output beam emitted from the output facet 12A, the fast axis beam width 330A, 330B is greater than the slow axis beam width 332A, 332B. More specifically, the beam emitted from the output facet 12A has a fast axis divergence angle of approximately sixty-eight degrees (68°), and a slow axis divergence angle of approximately fifty-two degrees (52°). Thus, the beam emitted from the output facet 12A is elliptical.

In the present examples, the optical assembly 16 is designed and positioned at the appropriate separation distance “L₁₊” (FIG. 3A) or “L₁₋” (FIG. 3B). As a result thereof, for the two solutions, (i) the fast axis beam width 330A, 330B is approximately equal to the slow axis beam width 332A, 332B near and after the dividing line 328; and (ii) the magnitude of the fast axis divergence angle is approximately equal to the magnitude of the slow axis divergence angle near and after the dividing line 328. In these examples, the adjusted beam have fast and slow axis divergence angles of approximately θ=3.2 mrad in the far-field.

It should be noted that four alternative locations along the propagation axis are also denoted in FIG. 3A with inverted triangles. These locations are individually referenced as Z0, Z1, Z2, and Z3, respectively. In this example, (i) Z0 is at the output facet 12A and thus Z0 has a value of zero meters (Z0)=0); (ii) Z1 is spaced apart from the output facet 12A along the propagation axis a distance of 0.44 meters (Z1)=0.44m); (iii) Z2 is spaced apart from the output facet 12A along the propagation axis a distance of 0.76 meters (Z2)=0.76m); and (iv) Z3 is spaced apart from the output facet 12A along the propagation axis a distance of 10 meters (Z3)=10m). In this example, (i) location Z0 is before the optical assembly 16, (ii) locations Z1 and Z2 are after the optical assembly 16 and are still in the near-field, and (iii) location Z3 is after the optical assembly 16 and is in the far-field.

FIGS. 3C-3F are simplified illustrations of four alternative beam profiles (x-y cross-sections) for the plus solution, with each beam profile being at a different distance along the optical axis, including both near field and far field locations. More specifically, (i) FIG. 3C illustrates the beam profile (for the plus solution) at position Z0=0 meters; (ii) FIG. 3D illustrates the beam profile at position Z1=0.44 meters; (iii) FIG. 3E illustrates the beam profile at position Z2=0.76 meters; and (iv) FIG. 3F illustrates the beam profile at position Z3=10 meters. It should be noted that the x and y dimensions in these plots have been scaled by the factor \sqrt{wₓ(z)w_{y}(z)} for visual aid. Referring to FIG. 3C, the output beam at the gain chip has an elliptical shape. Alternatively, referring to FIG. 3F, the output beam has circular shape in the far-field as a result of the present invention.

The parameters of the laser assembly used to generate the graphs in FIGS. 3A-3F are detailed in Table 3 below:

TABLE 3

| wₓ(0) | w_{y}(0) | λ₀ | f | Δ | 2θ |
|---|---|---|---|---|---|
| 3.25 μm | 2.45 μm | 4.6 μm | 2.54 mm | +/−5.44 μm | 3.2 mrad |

In Table 3, (i) λ₀ is the center wavelength of the output beam 14 in a vacuum; (ii) f is the effective focal length of the optical assembly 16; (iii) Δ-delta is the displacement of the output facet 12A relative to the front focal plane 16D of the optical assembly 16; (iv) 2θ is the full-angle 1/e (electric field) far-field divergence angle; (v) wₓ(0) is the slow axis beam radius at the output facet 12A of the gain chip 12; and (vi) w_{y} (0) is the fast axis beam radius at the output facet 12A of the gain chip 12.

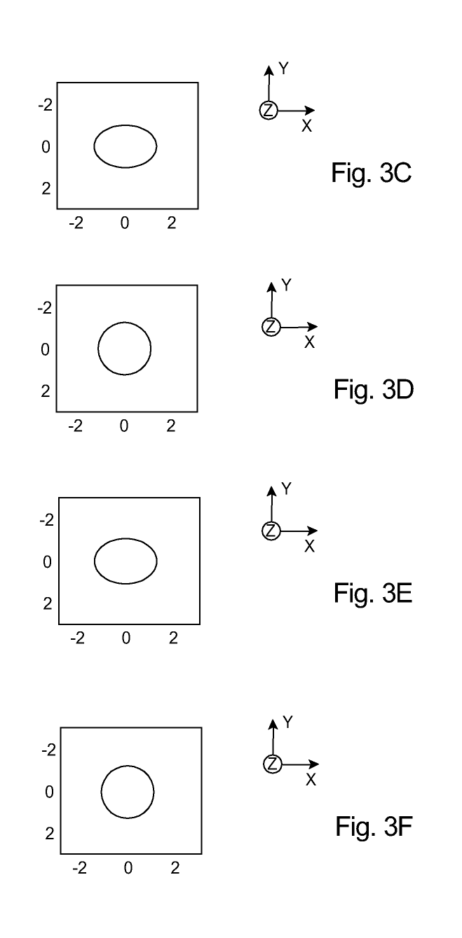

FIG. 4 is a simplified side illustration of a lens 16A having features of the present invention.

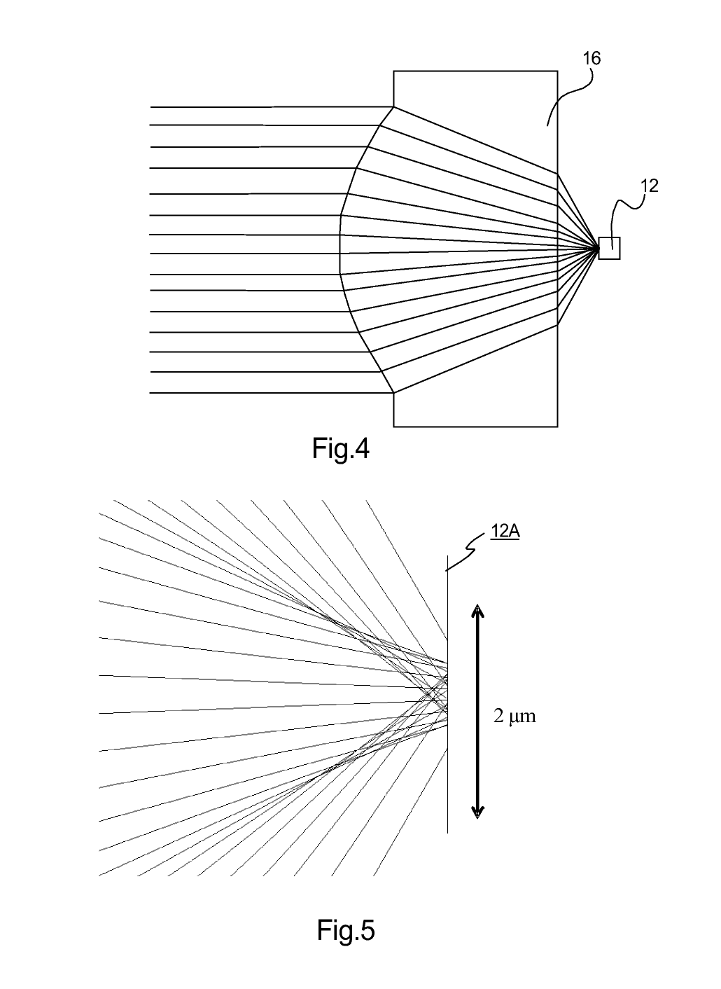

FIG. 5 is a simplified illustration of a ray fan plot at the output facet 12A of a gain chip.

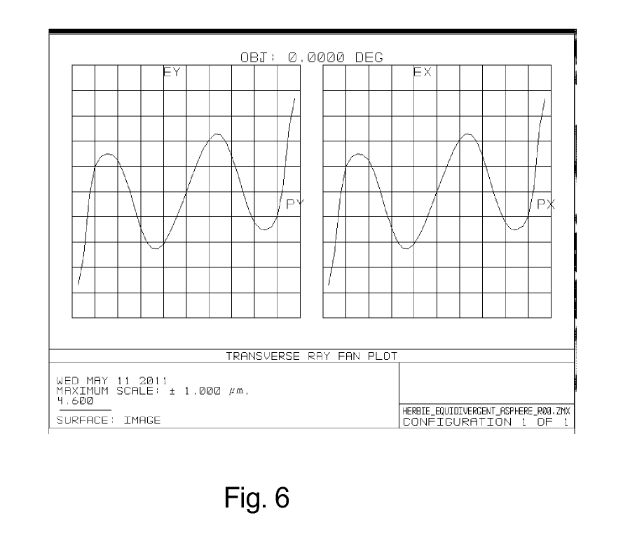

FIG. 6 is a transverse ray fan plot at the output facet.

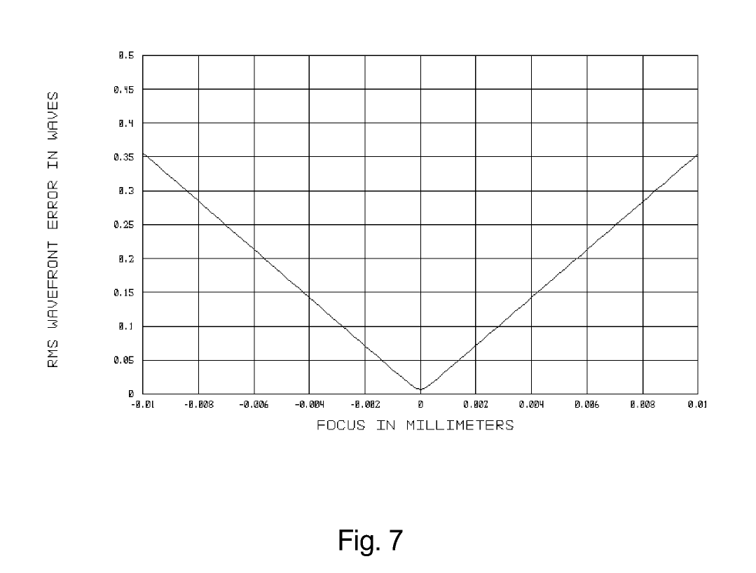

FIG. 7 is a graph that illustrates RMS wavefront error vs. focus measured in waves. In this non-exclusive example, the design achieves diffraction limit at facet location according to the Rayleigh criteria RMS error <λ/20.

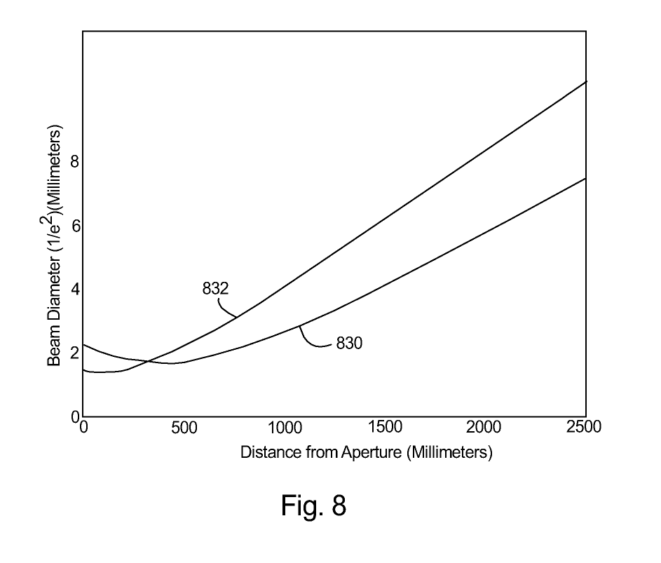

FIG. 8 is a simplified graph that illustrates fast axis beam diameter 830 and slow axis beam diameter 832 as a function of distance from the output facet of a collimated quantum cascade gain chip. The graph was generated using a combination of both measured and simulated results, and propagation curves 830, 832 represent the best fit of the measured and simulated results. In this example, the best fit beam propagation curves 830, 832 for the fast and slow axis data are wₓ(0)=3.7 microns (μm) and w_{y}(0)=2.4 microns (μm) for a wavelength of approximately 4.6 microns. For this example, using equation (2) from above, and with reference to FIG. 1A, the optimal position of the output facet 12A relative to the front focal plane 16D of the optical assembly 16 would be delta (Δ)=+/−6.06 microns.

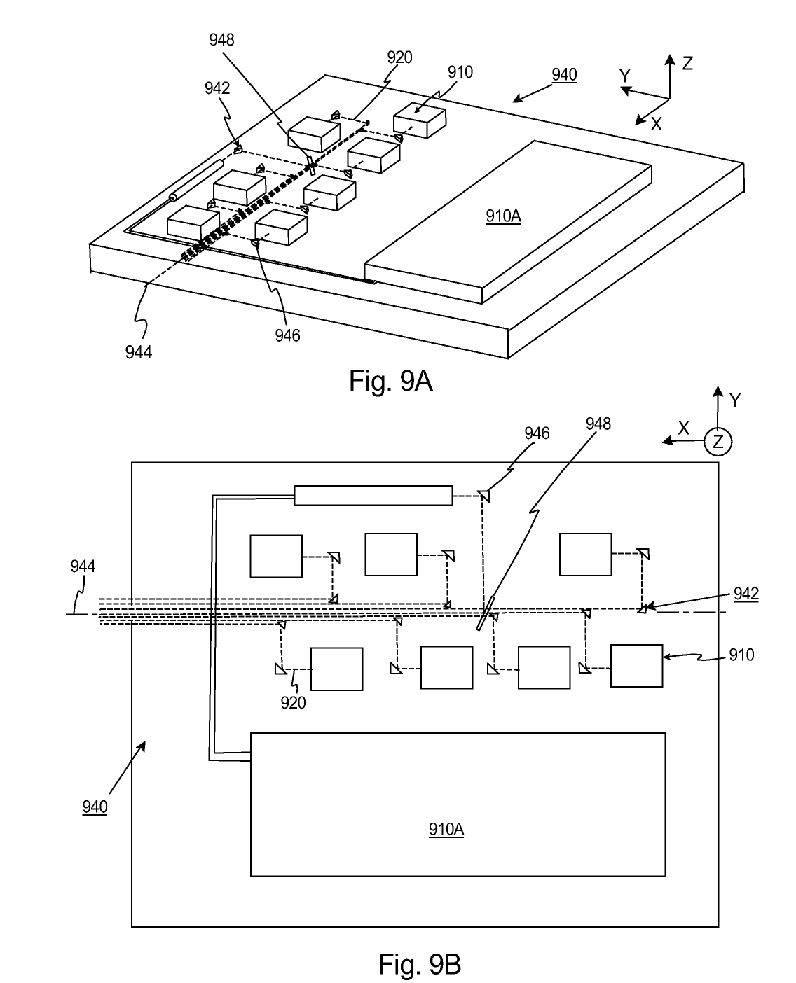

FIG. 9A is a perspective view and FIG. 9B is a top view of a laser source 940 having features of the present invention. These Figures illustrate that multiple laser assemblies 910 (including gain chip and lens) can be combined with a beam director assembly 942 to provide the high power laser source 940. In applications like this, accurately controlling the divergence of each beam 920 is critical to being able to tightly orient the beams, and efficiently coupling the beams on a fiber, while maintaining free-space laser spectral brightness.

The number of the laser assemblies 910 can be varied to achieve the desired characteristics of the laser source. In FIGS. 9A and 9B, the laser source 940 includes eight separate laser assemblies 910. In this embodiment, seven of the laser assemblies 910 are MIR laser sources, and one of the laser assemblies 910A is a non-MIR laser source. Alternatively, the laser source 940 can be designed to have more or fewer than seven MIR laser assemblies 910, and/or more than one or zero non-MIR laser sources 910A.

In this embodiment, the beam director assembly 942 directs the beams 920 so that they are parallel to each other, and are adjacent to or overlapping each other. As provided herein, in one embodiment, the beam director assembly 942 directs the MIR beams 920 and the non-MIR beam 920 in a substantially parallel arrangement with a combiner axis 944. Stated in another fashion, the beam director assembly 942 combines the beams 920 by directing the beams 920 to be parallel to each other (e.g. travel along parallel axes). Further, beam director assembly 942 causes the beams 920 to be directed in the same direction, with the beams 920 overlapping, or are adjacent to each other.

In one embodiment, the beam director assembly 942 can include a pair of individually adjustable beam directors 946 for each MIR laser assembly 910, and a dichroic filter 948 (or polarization filter). Each beam director 946 can be beam steering prism. Further, the dichroic filter 948 can transmit beams 920 in the MIR range while reflecting beams 920 in the non-MIR range.

More detail regarding a suitable laser source can be found in U.S. patent application Ser. No. 12/427,364, filed on Apr. 21, 2009. As far as permitted, the contents of U.S. patent application Ser. No. 12/427,364 are incorporated herein by reference.

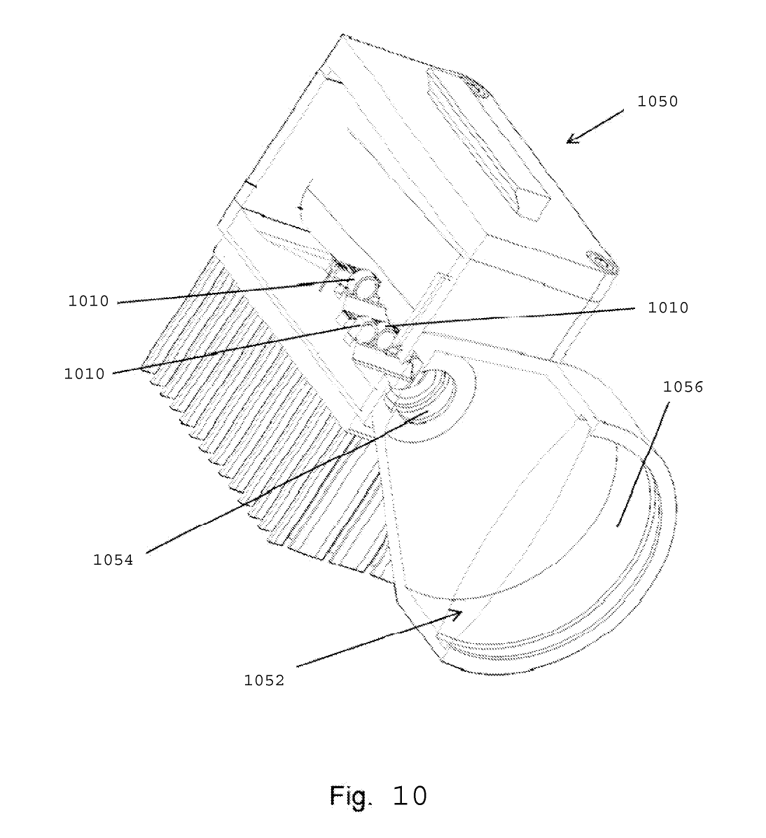

FIG. 10 is a perspective cut-away view of the thermal pointer 1050 having features of the present invention. In this embodiment, the thermal pointer 1050 includes multiple (e.g. three) laser assemblies 1010 (each including a gain chip and lens) and a beam adjuster assembly 1052. In this embodiment, the beam adjuster assembly 1052 is used to expand the beams from a smaller to a larger collimated beam diameter. Stated another way, the beam adjuster assembly 1052 is uniquely designed to minimize beam divergence, as low divergence is often a necessary characteristic in order to provide a smaller spot on the target at greater distances.

In one embodiment, the beam adjuster assembly 1052 is a two lens system that functions somewhat similar to a beam expanding telescope. More specifically, in this embodiment, the beam adjuster assembly 1052 includes a convex collimating diverging lens 1054, and a concave collimating assembly lens 1056. The diverging lens 1054 expands and/or diverges each of the beam generated by the laser assemblies 1010. Subsequently, the assembly lens 1056 re-collimates each of the beams. Stated in another manner, the assembly lens 1056 collimates the beams that have exited from the diverging lens 1054. Together, the lenses of the beam adjuster assembly 1052 are a beam expander, going from a smaller to a larger collimated beam diameter.

In FIG. 10, the diverging lens 1054 is closer to the laser assemblies 1010 than the assembly lens 1056. In certain non-exclusive alternative embodiments, the beam adjuster assembly 1052 can increase the diameter of a beam by a factor of between approximately 2 and 6, and reduce divergence accordingly.

More detail regarding a suitable thermal pointer can be found in U.S. patent application Ser. No. 13/303,088, filed on Nov. 22, 2011. As far as permitted, the contents of U.S. patent application Ser. No. 13/303,088 are incorporated herein by reference.

With the embodiments provided herein, the size of the output beam can be made minimally insensitive to axial (z) misalignment of the primary collimating optic at a distance L2 by locating the facet at a specified distance L1 from the front principal plane of the primary collimating lens system.

While a number of exemplary aspects and embodiments of a laser assembly 10 have been discussed above, those of skill in the art will recognize certain modifications, permutations, additions and sub-combinations thereof. It is therefore intended that any claims that may be hereafter introduced with regard to the present invention are interpreted to include all such modifications, permutations, additions and sub-combinations as are within their true spirit and scope.

What is claimed is:

1. A laser assembly for providing a beam, the laser assembly comprising:
a gain chip including an output facet, the gain chip emitting an astigmatic, output beam from the output facet when electrical power is directed to the gain chip, the astigmatic output beam exiting the output facet having a first axis divergence angle and a second axis divergence angle, and wherein a magnitude of the first axis divergence angle is different from a magnitude of the second axis divergence angle; and
a collimating, output optical assembly positioned in path of the output beam, the output optical assembly being axisymmetric about an optical axis, the output optical assembly adjusting the output beam so that an adjusted output beam exiting the output optical assembly has an adjusted first axis divergence angle and an adjusted second axis divergence angle, wherein a magnitude of the adjusted first axis divergence angle is approximately equal to a magnitude of an adjusted second axis divergence angle in a far field.

2. The laser assembly of claim 1 wherein aberrations of the optical assembly are corrected for finite conjugate points.

3. The laser assembly of claim 1 (i) wherein the gain chip is a gain medium having a fast axis and a slow axis; (ii) wherein the optical assembly has a front focal plane, a front principal plane, and a focal length; (iii) wherein the front principal plane of the optical assembly is spaced apart from the output facet a separation distance along a propagation axis of the output beam; and (iv) wherein the separation distance is approximately equal to the focal length plus or minus delta, with delta being equal to the boundary of the Rayleigh distance of a hypothetical axisymmetric Gaussian beam having a waist of radius equal to the geometric mean of the actual waists of the fast and slow axes of the gain medium.

4. The laser assembly of claim 1 (i) wherein the gain chip is a gain medium having a first axis and a second axis; (ii) wherein the optical assembly has a front focal plane, and a front principal plane; (iii) wherein the front principal plane of the optical assembly is spaced apart from the output facet a separation distance “L₁” along a propagation axis of the output beam; and (iv) wherein the separation distance is calculated utilizing the following formula:
$${L}_{1} = f \pm \frac{π {w}_{x} ( 0 ) {w}_{y} ( 0 )}{λ}$$
wherein (i) wₓ(0) is the Gaussian beam radius at the output facet in the second axis; (ii) w_{y}(0) is the Gaussian beam radius at the output facet in the first axis; (iii) λ is the wavelength of the output beam; and (iv) f is a focal length of the optical assembly and is measured with respect to the front principal plane of the optical assembly.

5. The laser assembly of claim 1 wherein the optical assembly is a single, collimating lens.

6. The laser assembly of claim 1 (i) wherein the gain chip is a gain medium having a fast axis and a slow axis; and (ii) wherein the optical assembly has the following imaging condition for two finite conjugate pairs (S₁,S₂) located at the following prescribed positions:
$${S}_{1} = - ( \frac{λ}{w} ) \frac{{f}^{2}}{{w}_{x} ( 0 ) {w}_{y} ( 0 )}$$
$${S}_{2} = f \pm \frac{π {w}_{x} ( 0 ) {w}_{y} ( 0 )}{λ}$$
wherein (i) wₓ(0) is the Gaussian beam radius at the output facet in the slow axis; (ii) w_{y}(0) is the Gaussian beam radius at the output facet in the fast axis; (iii) λ is the wavelength of the output beam; and (iv) f is a focal length of the optical assembly and is measured with respect to a front principal plane of the optical assembly.

7. The laser assembly of claim 1 wherein the gain chip is a quantum cascade or an interband cascade gain medium.

8. A method for assembling a laser assembly that generates an adjusted beam, the method comprising the steps of:
providing a gain chip that emits an astigmatic, output beam from an output facet;
providing a collimating optical assembly that is axisymmetric about an optical axis; and
positioning the optical assembly in the path of the output beam so that the optical assembly adjusts the output beam so that the adjusted output beam has an adjusted first axis divergence angle and an adjusted second axis divergence angle that are approximately equal in magnitude in a far field.

9. The method of claim 8 further comprising the step of correcting the aberrations of the optical assembly for finite conjugate points.

10. The method of claim 8 (i) wherein the step of providing a gain chip includes the gain chip being a gain medium having a fast axis and a slow axis; (ii) wherein the step of providing an optical assembly includes the optical assembly having a front focal plane, a front principal plane, and a focal length; (iii) wherein the step of positioning the optical assembly includes the step of positioning the optical assembly so that a front principal plane of the optical assembly is spaced apart from the output facet a separation distance along a propagation axis of the output beam; and the separation distance is approximately equal to the focal length plus or minus delta, with delta being equal to the boundary of the Rayleigh distance of a hypothetical axisymmetric Gaussian beam having a waist of radius equal to the geometric mean of the actual waists of the fast and slow axes of the gain medium.

11. The method of claim 8 (i) wherein the step of providing a gain chip includes the gain chip being a gain medium having a fast axis and a slow axis; (ii) wherein the step of providing an optical assembly includes the optical assembly having a front focal plane, a front principal plane, and a focal length; (iii) wherein the step of positioning the optical assembly includes the step of positioning the optical assembly so that the front principal plane of the optical assembly is spaced apart from the output facet a separation distance “L₁” along a propagation axis of the output beam; and (iv) wherein the separation distance is calculated utilizing the following formula:
$${L}_{1} = f \pm \frac{π {w}_{x} ( 0 ) {w}_{y} ( 0 )}{λ}$$
wherein (i) wₓ(0) is the Gaussian beam radius at the output facet in the second axis; (ii) w_{y}(0) is the Gaussian beam radius at the output facet in the first axis; (iii) λ is the operating wavelength of the gain medium; and (iv) f is a focal length of the optical assembly and is measured with respect to the front principal plane (FPP) of the optical assembly.

12. The method of claim 8 wherein the step of providing a collimating optical assembly includes providing a single, axisymmetric collimating lens.

13. The method of claim 8 (i) wherein the step of providing a gain chip includes the gain chip being a gain medium having a fast axis and a slow axis; (ii) wherein the step of providing an optical assembly includes the optical assembly having the following imaging condition for two finite conjugate pairs (S₁,S₂) located at the following prescribed positions:
$${S}_{1} = - ( \frac{λ}{π} ) \frac{{f}^{2}}{{w}_{x} ( 0 ) {w}_{y} ( 0 )}$$
$${S}_{2} = f \pm \frac{π {w}_{x} ( 0 ) {w}_{y} ( 0 )}{λ}$$
wherein (i) wₓ(0) is the Gaussian beam radius at the output facet in the second axis; (ii) w_{y}(0) is the Gaussian beam radius at the output facet in the first (fast) axis; (iii) λ is the operating wavelength of the gain medium; and (iv) f is a focal length of the optical assembly and is measured with respect to a front principal plane of the optical assembly.

14. The method of claim 8 (i) wherein the step of providing a gain chip includes providing a quantum cascade or an interband cascade gain medium.

15. A method for assembling a laser assembly that generates an adjusted output beam having an adjusted first axis divergence angle and an adjusted second axis divergence angle, wherein a ratio of the adjusted first axis divergence angle and the adjusted second axis divergence angle in a far field is equal to a predetermined, desired ratio that is not equal to one, the method comprising the steps of:
providing a gain chip that emits an astigmatic, output beam from an output facet along a propagation axis;
providing an axisymmetric collimating optical assembly having an optical axis; and
positioning the optical assembly in the path of the output beam along the propagation axis with the optical axis substantially coaxial with the propagation axis, wherein the optical assembly is positioned so that the optical assembly adjusts the output beam so that the adjusted output beam has a ratio of the magnitude of the adjusted first axis divergence angle and the magnitude of the adjusted second axis divergence angle in the far field that is approximately equal to the predetermined, desired ratio.

16. The method of claim 15 (i) wherein the step of providing a gain chip includes the gain chip being a gain medium having a fast axis and a slow axis; (ii) wherein the step of providing an optical assembly includes the optical assembly having a front focal plane, a front principal plane, and a focal length; (iii) wherein the step of positioning the optical assembly includes the step of positioning the optical assembly so that a front principal plane of the optical assembly is spaced apart from the output facet a separation distance along a propagation axis of the output beam; and the separation distance is approximately equal to the focal length plus or minus delta, with delta being equal to
$$Δ = \pm \frac{π {w}_{x} ( 0 ) {w}_{y} ( 0 )}{λ} \sqrt{\frac{η - {γ}^{2}}{1 + {ηγ}^{2}}} = \frac{π {\overline{w}}_{x , y}^{2}}{λ} \sqrt{\frac{η - {γ}^{2}}{1 + {ηγ}^{2}}}$$
wherein (i) wₓ(0) is the Gaussian beam radius at the output facet in the second axis; (ii) w_{y}(0) is the Gaussian beam radius at the output facet in the first axis; (iii) λ is the operating wavelength of the gain medium; (iv) η is the ratio, and (v)
$$γ ≡ \frac{{w}_{x} ( 0 )}{{w}_{y} ( 0 )} .$$

17. The method of claim 15 further comprising the step of correcting the aberrations of the optical assembly for finite conjugate points.

18. The method of claim 15 wherein the step of providing an axisymmetric collimating optical assembly includes providing a single, collimating lens.
